(19) United States
(12) Patent Application Publication
(10) Pub. No.: US 2003/0157791 A1
(43) Pub. Date: Aug. 21, 2003

(54) Process of fabricating bumps

(76) Inventors: Ho-Ming Tong, Taipei (TW); Chun-Chi Lee, Kaohsiung (TW); Jen-Kuang Fang, Pingtung Hsien (TW); Min-Lung Huang, Kaohsiung (TW); Jau-Shoung Chen, Hsinchu Hsien (TW); Ching-Huei Su, Kaohsiung (TW); Chao-Fu Weng, Tainan (TW); Yung-Chi Lee, Kaohsiung (TW)

Correspondence Address: J.C. Patents, Inc., 4 Venture, Suite 250, Irvine, CA, 92618, US

(21) Appl. No.: 10/372,546

(22) Filed: Feb. 21, 2003

(30) Foreign Application Priority Data
Feb. 21, 2002 (TW) 91102991

(51) Int. Cl. H01L 21/44

(52) U.S. Cl. 438/613; 438/614

(57) ABSTRACT

A process of forming bumps on conductive pads is provided. First, an adhesion layer made of titanium, titanium-wolfram alloy or chromium is formed on the conductive pads. Subsequently, a barrier layer made of nickel-vanadium alloy is formed on the adhesion layer. Next, a wettable layer made of copper is formed on the barrier layer. Subsequently, solder material is formed on the wettable layer. Subsequently, etching processes are performed to remove the wettable layer, the barrier layer and the adhesion layer that are exposed to the outside. The wettable layer, the barrier layer and the adhesion layer remain under the solder material. Afterward, a reflow process can be selectively performed.

### CROSS-REFERENCE TO RELATED APPLICATION

This application claims the priority benefit of Taiwan application serial no. 91102991, filed Feb. 21, 2002.

### BACKGROUND OF THE INVENTION

1. Field of the Invention

The invention relates in general to a process of fabricating bumps. More particularly, the invention relates to a process for fabricating bumps, which are provided with a barrier layer made of nickel-vanadium alloy, and the barrier layer can be etched by an etchant containing sulfuric acid.

2 . Description of the Related Art

Nowadays, electronic products are increasingly used to achieve many various tasks. With the development of electronics technology, miniaturization, multi-function task, and comfort of utilization are among the principle guidelines of electronic product manufacturers. As far as the profile of electronic products is concerned, lightness, thinness and smallness are the trend to design them. With the current of the design style, there are many semiconductor packages with high density having been researched in semiconductor-package technology. For example, the technology of a flip-chip package can be used to achieve the design rules. In the flip-chip package, there are many bumps formed on conductive pads of a chip, and the bumps can electrically connect the chip with a substrate. Comparing with electrical connection type of bonding wires and bonding a tape carrier, the flip-chip package has a short electrical connection path, so it can provide electrical connection with high quality. In addition, for a flip-chip package, a heat sink can be directly attached onto the backside of a chip to enhance the convective heat dissipation. Based on the above reason, the flip-chip package is popular in the semiconductor package industry.

FIGS. 1-7 are various cross-sectional views showing a process of fabricating bumps according to U.S. Pat. No. 5,508,229. Referring to FIG. 1, a wafer 110 is provided with an active surface 112. The wafer 110 has a passivation layer 114 and many conductive pads 116 (only shown one of them) positioned on the active surface 112 of the chip 110. The passivation layer 114 has many openings exposing the conduction pads 116.

As shown in FIG. 2, a sputter process or an evaporation process is used to form an adhesion layer 120 onto the active surface 112 of the chip 110, and the adhesion layer 120 covers the passivation layer 114 and the conductive pads 116. The material of the adhesion layer 120 is aluminum. Subsequently, an electroplating process, a sputter process or an evaporation process is used to form a barrier layer 130 onto the adhesion layer 120, wherein the material of the barrier layer 130 is nickel-vanadium alloy. Next, an electroplating process, a sputter process or an evaporation process is used to form a wettable layer 140 onto the barrier layer 130, wherein the material of the wettable layer 140 is copper. Fabricating an under bump metallurgy 142 containing the adhesion layer 120, the barrier layer 130, and the wettable layer 140 is finished so far.

Next, referring to FIG. 3, a photolithography process is performed. First, a photoresist layer 150 is formed onto the wettable layer 140 and, then, an exposure process, a development process and other processes are used to transfer a pattern (not shown) to the photoresist layer 150, whereby there are many openings formed through the photoresist layer 150 and exposing the wettable layer 140 positioned over the conductive pads 116.

Next, referring to FIG. 4, an electroplating process is used to fill solder material 160 (only shown one of them) into the openings 152 of the photoresist layer 150. The solder material 160 covers the wettable layer 140. Subsequently, the photoresist layer 150 is removed from the surface of the wettable layer 140, as shown in FIG. 5. Afterward, an etchant is used to remove the under bump metallurgy 142 exposed to the outside, and the under bump metallurgy 142 remains under the solder material 160. The passivation layer 114 of the wafer 110 is exposed to the outside, as shown in FIG. 6. The composition of this etchant is approximately in the range of 1 to 25% by volume phosphoric acid, 1 to 10% by volume acetic acid, 0.1 to 2% by volume hydrogen peroxide, and 63 to 98% by volume deionized (DI) water. The etching process can be done at about 70.degree. C. The wettable layer 120, the barrier layer 130 and the adhesion layer 120 can be removed by only one etching process using the above etchant.

Subsequently, referring to FIG. 7, a reflow process is performed. After a flux is sprayed on the solder material 160, during a heating process the solder material 160 softens and shapes like balls. Fabricating bumps 170 including the under bump metallurgy 142 and the solder material 160 is finished so far.

In the above conventional process, the etchant concentration, etching time, etching temperature and other parameters can be regulated to control the etching speed. However, the regulation of the etching speed is in a limited scope.

### SUMMARY OF THE INVENTION

Accordingly, an objective of the present invention is to provide a process for fabricating bumps which are provided with a barrier layer made of nickel-vanadium alloy, and the barrier layer can be etched by an etchant containing sulfuric acid.

To achieve the foregoing and other objectives, the present invention provides a process for fabricating bumps on a wafer. The wafer has an active surface. The wafer is provided with a passivation layer and many conductive pads. The passivation layer and the conductive pads are on the active surface of the wafer. The process for fabricating bumps comprises the following steps.

An adhesion layer is first formed onto the active surface of the wafer and covers the conductive pads and the passivation layer, wherein the material of the adhesion layer can be titanium, titanium-wolfram alloy, or chromium. Next, a barrier layer is formed onto the adhesion layer, wherein the material of the barrier layer can be nickel-vanadium alloy. Subsequently, a wettable layer is formed onto the barrier layer, wherein the material of the wettable layer can be copper.

Subsequently, a photolithography process is performed. A photoresist layer is formed onto the wettable layer and there are many openings formed through the photoresist layer and exposing the wettable layer. Afterward, solder material is filled into the openings and covers the wettable layer. Next, the photoresist is removed.

Subsequently, etching processes are used to remove the wettable layer, the barrier layer and the adhesion layer that are exposed to the outside, and the wettable layer, the barrier layer and the adhesion layer remain under the solder material. The passivation layer is exposed to the outside. Finally, a reflow process is used to make the solder material shaped like balls.

According to the above process, provided that the adhesion layer is made of titanium-wolfram alloy, during the etching process the etchant contains hydrogen peroxide (H₂O₂), ethylenediaminetetraacetic (EDTA), and potassium sulfate (K₂SO₄) whereby only slightly is the solder material damaged. Provided that the adhesion layer is made of chromium, during the etching process the etchant contains hydrochloric acid (HCl) whereby only slightly is the solder material damaged. Provided that the adhesion layer is made of titanium, during the etching process the etchant. contains ammonium hydroxide (NH₄OH) and hydrogen peroxide (H₂O₂) whereby only slightly is the solder material damaged, or the etchant also can be hydrofluoric acid (HF). The etchant for etching the barrier layer made of nickel-vanadium alloy contains sulfuric acid. The etchant for etching the wettable layer made of copper can the solution composed of ammonium hydroxide (NH₄OH) and hydrogen peroxide (H₂O₂) or the solution composed of potassium sulfate (K₂SO₄) and glycerol.

Both the foregoing general description and the following detailed description are exemplary and explanatory only and are not restrictive of the invention, as claimed. It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. A simple description of the drawings is as follows.

FIGS. 1-7 are various cross-sectional views showing a process of fabricating bumps according to U.S. Pat. No. 5,508,229.

FIGS. 8-15 are various cross-sectional views showing a process of fabricating bumps according to an embodiment of the present invention.

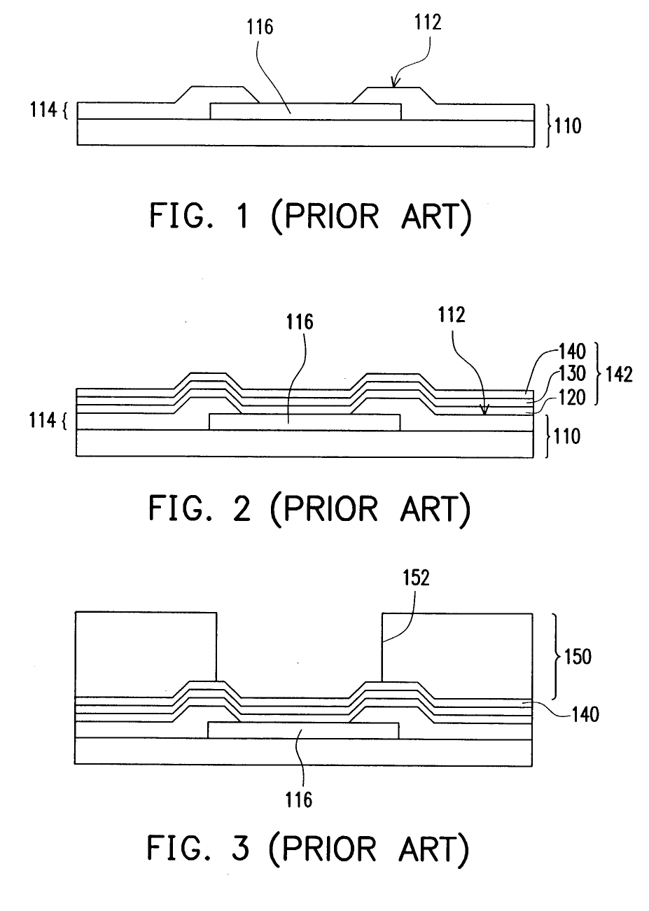

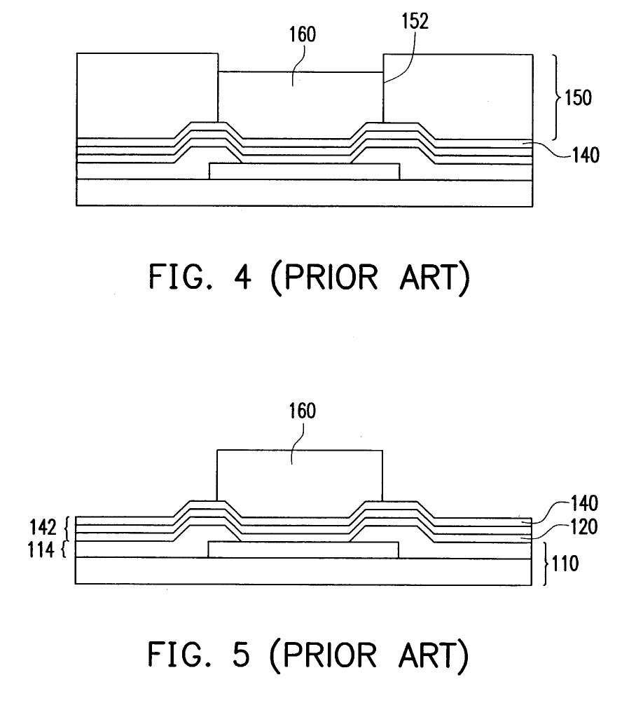

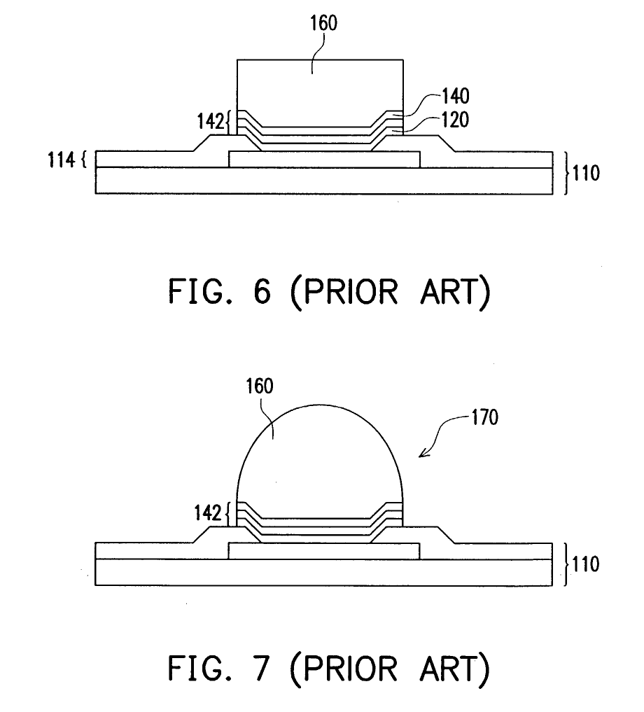

### DESCRIPTION OF THE PREFERRED EMBODIMENTS

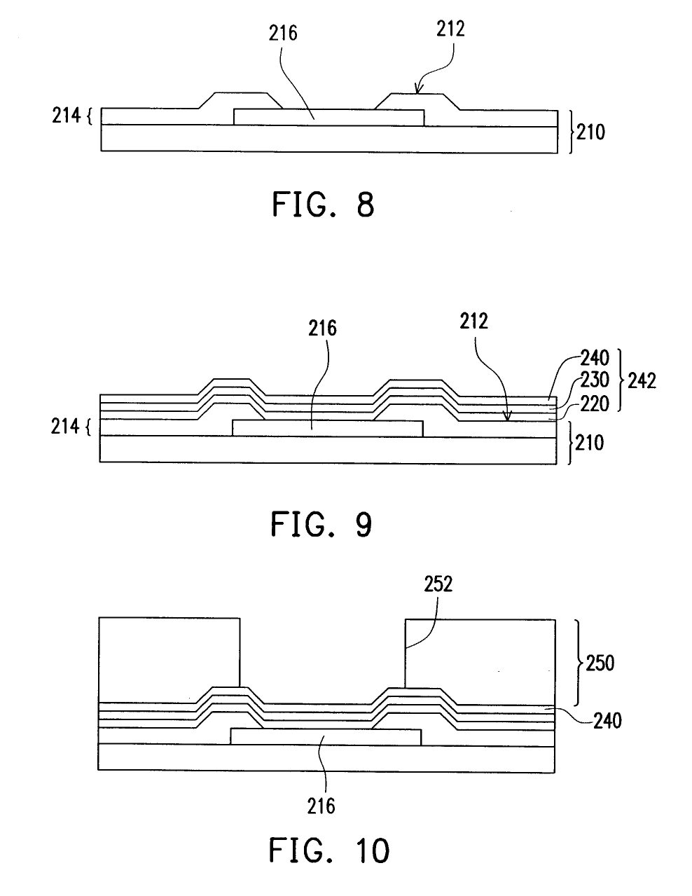

FIGS. 8-15 are various cross-sectional views showing a process of fabricating bumps according to an embodiment of the present invention. Referring to FIG. 8, a wafer 210 is provided with an active surface 212. The wafer 210 has a passivation layer 214 and many conductive pads 216 (only shown one of them) positioned on the active surface 212 of the chip 210. The passivation layer 214 has many openings exposing the conduction pads 216. The main material of the conduction pads 216 can be copper of aluminum.

As shown in FIG. 9, a sputter process or an evaporation process is used to form an adhesion layer 220 onto the active surface 212 of the chip 210, and the adhesion layer 220 covers the passivation layer 214 and the conductive pads 216. The material of the adhesion layer 120 can be, for example, aluminum, titanium, titanium-wolfram alloy, or chromium. Subsequently, an electroplating process, a sputter process or an evaporation process is used to form a barrier layer 230 onto the adhesion layer 220, wherein the material of the barrier layer 230 is, for example, nickel-vanadium alloy. Next, an electroplating process, a sputter process or an evaporation process is used to form a wettable layer 240 onto the barrier layer 230, wherein the material of the wettable layer 140 can be, for example, copper, palladium, or gold. Fabricating an under bump metallurgy 242 containing the adhesion layer 220, the barrier layer 230, and the wettable layer 240 is finished so far.

Next, referring to FIG. 10, a photolithography process is performed. First, a photoresist layer 250 is formed onto the wettable layer 240 and, then, an exposure process, a development process and other processes are used to transfer a pattern (not shown) to the photoresist layer 250, whereby there are many openings formed through the photoresist layer 250 and exposing the wettable layer 240 positioned over the conductive pads 216.

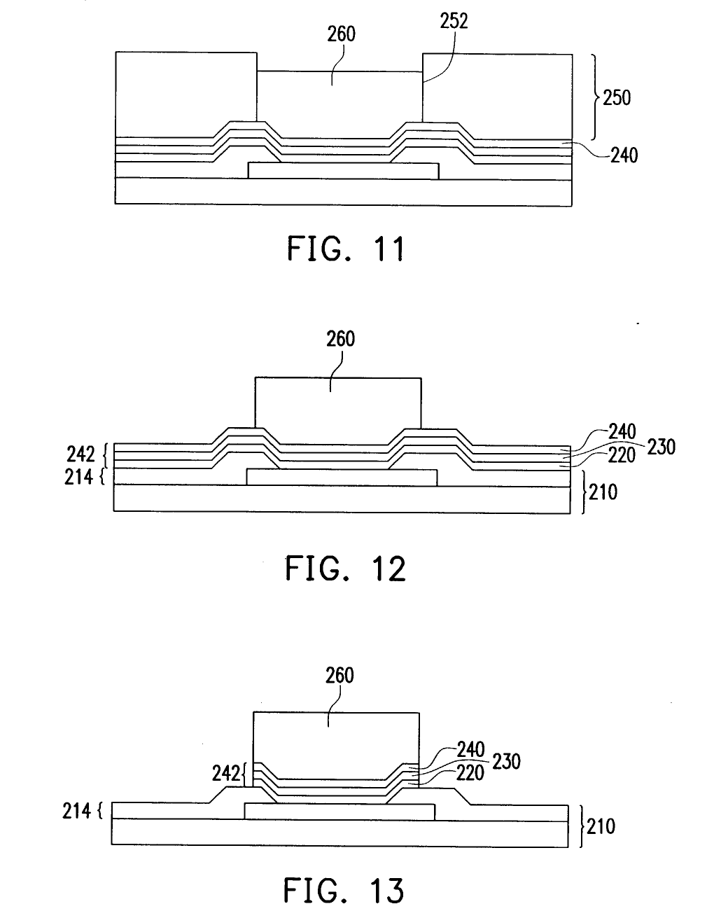

Next, referring to FIG. 11, an electroplating process is used to fill solder material 260 (only shown one of them) into the openings 252 of the photoresist layer 250. The solder material 260 covers the wettable layer 240, wherein the solder material 260 can be, for example, tin-lead alloy, gold or lead-free material. Subsequently, the photoresist layer 250 is removed from the surface of the wettable layer 240, as shown in FIG. 12. Afterward, etching processes are used to remove the under bump metallurgy 242 exposed to the outside, and the under bump metallurgy 242 remains under the solder material 260. The passivation layer 214 of the wafer 210 is exposed to the outside, as shown in FIG. 13. Provided that the adhesion layer is made of titanium-wolfram alloy, during the etching process the etchant, incorporated in U.S. Pat. No. 5,462,638, contains hydrogen peroxide (H₂O₂), ethylenediaminetetraacetic (EDTA), and potassium sulfate (K₂SO₄) whereby only slightly is the solder material damaged. Provided that the adhesion layer is made of chromium, during the etching process the etchant, incorporated in U.S. Pat. No. 5,162,257, contains hydrochloric acid (HCl) whereby only slightly is the solder material damaged. Provided that the adhesion layer is made of titanium, during the etching process the etchant, incorporated in U.S. Pat. No. 5,162,257, contains ammonium hydroxide (NH₄OH) and hydrogen peroxide (H₂O₂) whereby only slightly is the solder material damaged, or the etchant also can be hydrofluoric acid (HF). Provided that the adhesion layer is made of aluminum, during the etching process the etchant, incorporated in U.S. Pat. No. 5,508,229, contains phosphoric acid and acetic acid. The etchant for etching the wettable layer made of copper can the solution, incorporated in U.S. Pat. No. 6,222,279, composed of ammonium hydroxide (NH₄OH) and hydrogen peroxide (H₂O₂) or the solution, incorporated in U.S. Pat. No. 5,486,282 and U.S. Pat. No. 5,937,320, composed of potassium sulfate (K₂SO₄) and glycerol.

The etchant for etching the barrier layer made of nickel-vanadium alloy contains sulfuric acid (H₂SO₄). The operating condition is described in the following.

In the first case, from about 1 weight percent to 98 weight percent of sulfuric acid (H₂SO₄) is used to etch the barrier layer 230 at room temperature. The etching process takes over 2 hours.

In the second case, from about 1 weight percent to 98 weight percent of sulfuric acid (H₂SO₄) is used to etch the barrier layer 230 at above 80 centigrade degrees. The etching process takes over 2 hours.

In the third case, an electrochemical etching process can be used to etch the barrier layer 230. For example, 10 weight percent of sulfuric acid (H₂SO₄) is used to etch the barrier layer 230 at room temperature on condition that an electric current density of from 0.001 to 0.02 A/cm², preferably 0.0025 A/cm², is applied. The etching process takes from about 20 to about 110 seconds, preferably about 20 to about 40 seconds. A constant current or a pulse current can be applied during etching.

In the above three etching cases, only slightly is the solder material damaged during etching. Besides, sulfuric acid (H₂SO₄) is easily sourced and costs low.

In the above etching process, in order to prevent the preceding etchant from remaining over the active surface of the wafer and on the solder material, before the following etching, deionized water can be used to wash the solder material and where is placed over the active surface of the wafer, whereby the yield of fabricating bumps is ensured.

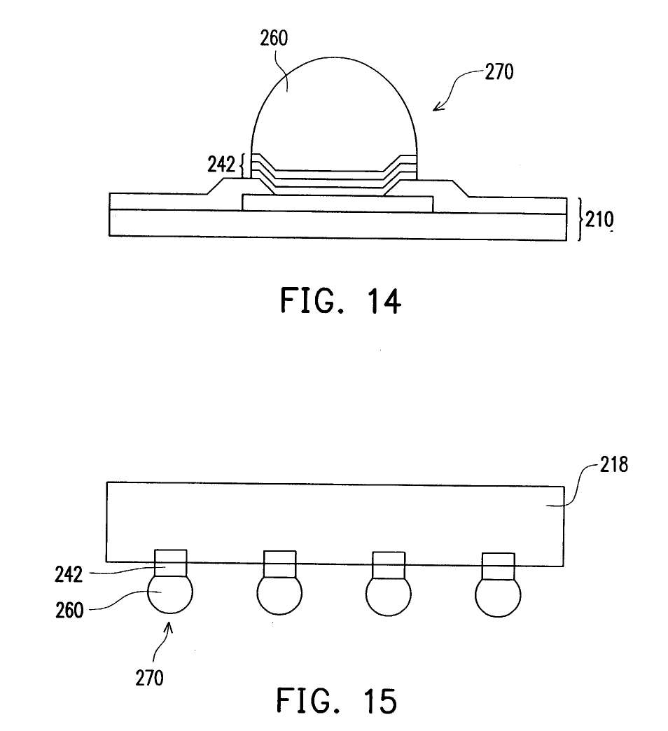

Subsequently, referring to FIG. 14, a reflow process can be selectively performed. After a flux is sprayed on the solder material, during a heating process the solder material 260 softens and shapes like balls. Fabricating bumps 270 including the under bump metallurgy 242 and the solder material 260 is finished so far. Finally, the wafer 210 is cut to create many chips 218, as shown in FIG. 15.

In the above etching process, the etchants for etching the adhesion layer, the barrier layer and the wettable layer have a weak ability to corrode the solder material. As a result, the solder material can be prevented from being largely damaged by the etchants and the volume of the solder material can be readily controlled. In addition, the under bump metallurgy 242 can be formed not only on the conductive pads made of aluminum but on the conductive pads made of copper.

Besides, the under bump metallurgy according to the invention is not limited to the structure with three layers, i.e. an adhesion layer, a barrier layer and a wettable layer, but the under bump metallurgy also can be formed with four conductive layers or two conductive layers. For example, the structure with four conductive layers can be constructed from a chromium layer, a chromium-copper alloy layer, a copper layer, and a silver layer. In the structure with two conductive layers, the bottom conductive layer can be titanium or titanium-wolfram alloy and the top conductive layer can be copper, nickel or gold.

In addition, the bumps are not limited to be formed on the active surface of the chip, but after a redistribution layer is formed on the active surface of the wafer, the bumps also can be formed on conductive pads of the redistribution layer. The fabrication of the redistribution layer should be known by those skilled in the art and, thus, is not described any more herein.

To sum up, the embodiment of the invention discloses many kinds of under bump metallurgy as shown in the following table.

| | | | Wettable |
|---|---|---|---|
| | Adhesion layer | Barrier layer | layer |
| The 1^{st} combination | titanium-wolfram | nickel-vanadium | copper |
| The 2^{nd} combination | titanium-wolfram | nickel-vanadium | palladium |
| The 3^{rd} combination | titanium-wolfram | nickel-vanadium | gold |
| The 4^{th} combination | chromium | nickel-vanadium | copper |
| The 5^{th} combination | chromium | nickel-vanadium | palladium |
| The 6^{th} combination | chromium | nickel-vanadium | gold |
| The 7^{th} combination | titanium | nickel-vanadium | copper |
| The 8^{th} combination | titanium | nickel-vanadium | palladium |
| The 9^{th} combination | titanium | nickel-vanadium | gold |
| The 10^{th} combination | aluminum | nickel-vanadium | copper |
| The 11^{th} combination | aluminum | nickel-vanadium | palladium |
| The 12^{th} combination | aluminum | nickel-vanadium | gold |

All of the above twelve kinds of under bump metallurgy can be formed on conductive pads made of copper or aluminum.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A process for fabricating bumps on a wafer, the wafer having an active surface, the wafer being provided with a passivation layer and a plurality of conductive pads, both the passivation layer and the conductive pads being positioned on the active surface of the wafer, the process for fabricating bumps comprising the steps of:
forming an adhesion layer onto the active surface of the wafer, the adhesion layer covering the conductive pads and the passivation layer, wherein the material of the adhesion layer includes titanium;
forming a barrier layer onto the adhesion layer, wherein the material of the barrier layer includes nickel-vanadium alloy;
forming a wettable layer onto the barrier layer;
forming a photoresist layer onto the wettable layer, wherein a plurality of openings are formed through the photoresist layer and expose the wettable layer;
filling a solder matel into the openings of the photoresist layer and the solder material covering the wettable layer;
removing the photoresist layer;
performing etching processes to remove the wettable layer, the barrier layer and the adhesion layer that are exposed to the outside, the wettable layer, the barrier layer and the adhesion layer remaining under the solder material, wherein an etchant for etching the barrier layer includes sulfuric acid; and
performing a reflow process to make the solder material into a ball-like shape.

2. The process according to claim 1, wherein the material of the wettable layer includes copper, and during the step of performing etching processes, an etchant for etching the wettable layer includes ammonium hydroxide and hydrogen peroxide.

3. The process according to claim 1, wherein during the step of performing etching processes, the barrier layer is etched using an electrochemical etching process.

4. The process according to claim 1, wherein during the step of performing etching processes, an etchant for etching the adhesion layer includes ammonium hydroxide and hydrogen peroxide.

5. The process according to claim 1, wherein during the step of performing etching processes, an etchant for etching the adhesion layer includes hydrofluoric acid.

6. The process according to claim 1, wherein the material of the wettable layer includes copper, and during the step of performing etching processes, an etchant for etching the wettable layer includes potassium sulphate and glycerol.

7. A process for fabricating bumps on a wafer, the wafer having an active surface, the wafer being provided with a passivation layer and a plurality of conductive pads, both the passivation layer and the conductive pads being positioned on the active surface of the wafer, the process for fabricating bumps comprising the steps of:
forming an adhesion layer onto the active surface of the wafer, the adhesion layer covering the conductive pads and the passivation layer, wherein the material of the adhesion layer includes aluminum;
forming a barrier layer onto the adhesion layer, wherein the material of the barrier layer includes nickel-vanadium alloy;
forming a wettable layer onto the barrier layer;
forming a photoresist layer onto the wettable layer, wherein a plurality of openings are formed through the photoresist layer and expose the wettable layer;
filling a solder matel into the openings of the photoresist layer and the solder material covering the wettable layer;
removing the photoresist layer;
performing etching processes to remove the wettable layer, the barrier layer and the adhesion layer that are exposed to the outside, the wettable layer, the barrier layer and the adhesion layer remaining under the solder material, wherein an etchant for etching the barrier layer includes sulfuric acid; and
performing a reflow process to make the solder material into a ball-like shape.

8. The process according to claim 7, wherein the material of the wettable layer includes copper, and during the step of performing etching processes, an etchant for etching the wettable layer includes ammonium hydroxide and hydrogen peroxide.

9. The process according to claim 7, wherein during the step of performing etching processes, the barrier layer is etched using an electrochemical etching process.

10. The process according to claim 7, wherein during the step of performing etching processes, an etchant for etching the adhesion layer includes phosphoric acid and acetic acid.

11. The process according to claim 7, wherein the material of the wettable layer includes copper, and during the step of performing etching processes, an etchant for etching the wettable layer includes potassium sulphate and glycerol.

12. A process for fabricating bumps on a wafer, the wafer having an active surface, the wafer being provided with a passivation layer and a plurality of conductive pads, both the passivation layer and the conductive pads being positioned on the active surface of the wafer, the process for fabricating bumps comprising the steps of:
forming an adhesion layer onto the active surface of the wafer, the adhesion layer covering the conductive pads and the passivation layer, wherein the material of the adhesion layer includes titanium-wolfram alloy;
forming a barrier layer onto the adhesion layer, wherein the material of the barrier layer includes nickel-vanadium alloy;
forming a wettable layer onto the barrier layer;
forming a photoresist layer onto the wettable layer, wherein a plurality of openings are formed through the photoresist layer and expose the wettable layer;
filling a solder material into the openings of the photoresist layer and the solder material covering the wettable layer;
removing the photoresist layer;
performing etching processes to remove the wettable layer, the barrier layer and the adhesion layer that are exposed to the outside, the wettable layer, the barrier layer and the adhesion layer remaining under the solder material, wherein an etchant for etching the barrier layer includes sulfuric acid; and
performing a reflow process to make the solder material into a ball-like shape.

13. The process according to claim 12, wherein the material of the wettable layer includes copper, and during the step of performing etching processes, an etchant for etching the wettable layer includes ammonium hydroxide and hydrogen peroxide.

14. The process according to claim 12, wherein during the step of performing etching processes, the barrier layer is etched using an electrochemical etching process.

15. The process according to claim 12, wherein during the step of performing etching processes, an etchant for etching the adhesion layer includes hydrogen peroxide, ethylenediaminetetraacetic, and potassium sulphate.

16. The process according to claim 12, wherein the material of the wettable layer includes copper, and during the step of performing etching processes, an etchant for etching the wettable layer includes potassium sulphate and glycerol.

17. A process for fabricating bumps on a wafer, the wafer having an active surface, the wafer being provided with a passivation layer and a plurality of conductive pads, both the passivation layer and the conductive pads being positioned on the active surface of the wafer, the process for fabricating bumps comprising the steps of:
forming an adhesion layer onto the active surface of the wafer, the adhesion layer covering the conductive pads and the passivation layer, wherein the material of the adhesion layer includes chromium;
forming a barrier layer onto the adhesion layer, wherein the material of the barrier layer includes nickel-vanadium alloy;
forming a wettable layer onto the barrier layer;
forming a photoresist layer onto the wettable layer, wherein a plurality of openings are formed through the photoresist layer and expose the wettable layer;
filling a solder material into the openings of the photoresist layer and the solder material covering the wettable layer;
removing the photoresist layer;
performing etching processes to remove the wettable layer, the barrier layer and the adhesion layer that are exposed to the outside, the wettable layer, the barrier layer and the adhesion layer remaining under the solder material, wherein an etchant for etching the barrier layer includes sulfuric acid; and
performing a reflow process to make the solder material into a ball-like shape.

18. The process according to claim 17, wherein the material of the wettable layer includes copper, and during the step of performing etching processes, an etchant for etching the wettable layer includes ammonium hydroxide and hydrogen peroxide.

19. The process according to claim 17, wherein during the step of performing etching processes, the barrier layer is etched using an electrochemical etching process.

20. The process according to claim 17, wherein during the step of performing etching processes, an etchant for etching the adhesion layer includes hydrochloric acid.

21. The process according to claim 17, wherein during the material of the wettable layer includes copper, and the step of performing etching processes, an etchant for etching the wettable layer includes potassium sulphate and glycerol.
